(19) United States
(12) Patent Application Publication
(10) Pub. No.: US 2020/0203036 A1
(43) Pub. Date: Jun. 25, 2020

(54) WIRE HARNESS

(71) Applicants: AutoNetworks Technologies, Ltd., Mie (JP); Sumitomo Wiring Systems, Ltd., Mie (JP); SUMITOMO ELECTRIC INDUSTRIES, LTD., Osaka (JP)

(72) Inventors: Housei MIZUNO, Mie (JP); Hiroki HIRAI, Mie (JP); Makoto HIGASHIKOZONO, Mie (JP); Hidetoshi ISHIDA, Mie (JP); Yasuo OMORI, Mie (JP)

(73) Assignees: AutoNetworks Technologies, Ltd., Mie (JP); Sumitomo Wiring Systems, Ltd., Mie (JP); SUMITOMO ELECTRIC INDUSTRIES, LTD., Osaka (JP)

(21) Appl. No.: 16/614,963

(22) PCT Filed: May 14, 2018
(86) PCT No.: PCT/JP2018/018550

§ 371 Date: Nov. 19, 2019

(30) Foreign Application Priority Data
Jun. 1, 2017 (JP) 2017-109045

(51) Int. Cl. H01B 7/00; H05K 1/18

(52) U.S. Cl. CPC H01B 7/0045; H05K 2201/10189; H05K 1/189

(57) ABSTRACT

A wire harness includes an electrical wire with sheet material and a tension bearing part. The electrical wire with sheet material includes a sheet material and an electrical wire fixed to the sheet material. The tension bearing part is provided on the sheet material to bear part of tension applied to the electrical wire in a state where the tension is applied to the electrical wire with sheet material.

### TECHNICAL FIELD

The present invention relates to a wire harness.

### BACKGROUND ART

Patent Document 1 discloses a wire harness in which a sheet material is fixed to an electrical wire by a double-sided adhesive tape.

As a technique of simply attaching the sheet material to the electrical wire, the applicant of the present application proposes a wire harness in which the electrical wire is sewn to the sheet material by a thread and a wire harness in which the electrical wire is welded to the sheet material.

### PRIOR ART DOCUMENTS

### Patent Documents

Patent Document 1: Japanese Patent Application Laid-Open No. 2015-72798

### SUMMARY

### Problem to be Solved by the Invention

In such wire harnesses in which the sheet material is fixed to the electrical wire, when the sheet material is made up of a member having high tension strength, increase in tension load on the electrical wire can be suppressed. However, when the sheet material is made up of a member having low tension strength, there is a possibility that excess tension load is applied to the electrical wire.

An object of the present invention is to provide a technique capable of suppressing excess tension load applied to an electrical wire even when a sheet material is made up of a member having low tension strength in a wire harness in which the electrical wire is fixed to the sheet material.

### Means to Solve the Problem

In order to solve the above problem, a wire harness according to a first aspect includes: an electrical wire with sheet material including a sheet material and an electrical wire fixed to the sheet material; and a tension bearing part provided on the sheet material to bear part of tension applied to the electrical wire in a state where the tension is applied to the electrical wire with sheet material.

The wire harness according to a second aspect is the wire harness according to the first aspect, wherein the tension bearing part includes a reinforcement member provided as a member different from the electrical wire with sheet material.

The wire harness according to a third aspect is the wire harness according to the second aspect, wherein the reinforcement member includes a thread sewn to the sheet material.

The wire harness according to a fourth aspect is the wire harness according to the third aspect, wherein the thread is linearly sewn to the sheet material.

A wire harness according to a fifth aspect is the wire harness according to any one of the second to fourth aspects, wherein the reinforcement member includes a dummy electrical wire provided together with the electrical wire and fixed to the sheet material.

A wire harness according to a sixth aspect is the wire harness according to any one of the second to fifth aspects, wherein the reinforcement member includes a hardly-stretchable member formed of a material less stretchable than a material of the electrical wire.

A wire harness according to a seventh aspect is the wire harness according to any one of the first to sixth aspects, wherein the tension bearing part includes a folding part formed by folding back part of the sheet material.

A wire harness according to an eighth aspect is the wire harness according to any one of the first to seventh aspects, wherein the electrical wire is fixed to the sheet material by sewing or welding.

### Effects of the Invention

According to the first to eighth aspects, the tension bearing part is provided, thereby being able to reduce the tension applied to the electrical wire. Accordingly, excess tension load applied to the electrical wire can be suppressed even when the sheet material is made up of a member having low tension strength in the wire harness in which the electrical wire is fixed to the sheet material.

Particularly, according to the second aspect, the tension bearing part corresponding to the tension applied to the electrical wire with sheet material can be simply provided.

Particularly, according to the third aspect, when the electrical wire is sewn and fixed to the sheet material, for example, the thread as the reinforcement member can be sewn to the sheet material using the same facility.

Particularly, according to the fourth aspect, the thread has a short extra length and is likely to bear the tension applied to the electrical wire with sheet material.

Particularly, according to the fifth aspect, when the electrical wire is fixed to the sheet material, the dummy electrical wire can be fixed to the sheet material by the same fixing method.

Particularly, according to the sixth aspect, the reinforcement member can bear a higher percentage of the tension applied to the electrical wire with sheet material.

Particularly, according to the seventh aspect, the tension bearing part can be simply provided by using the sheet material.

Particularly, according to the eighth aspect, the electric wire can be simply fixed to the sheet material.

### BRIEF DESCRIPTION OF DRAWINGS

FIG. 1 A perspective view illustrating a wire harness according to an embodiment.

FIG. 2 A partial schematic cross-sectional view illustrating the wire harness according to the embodiment.

FIG. 3 A partial schematic cross-sectional view illustrating a modification example of a thread as a tension bearing part.

FIG. 4 A perspective view illustrating a wire harness according to a first modification example.

FIG. 5 A perspective view illustrating a wire harness according to a second modification example.

FIG. 6 A perspective view illustrating a wire harness according to a third modification example.

FIG. 7 A perspective view illustrating a wire harness according to a fourth modification example.

FIG. 8 A perspective view illustrating a wire harness according to a fifth modification example.

### DESCRIPTION OF EMBODIMENT(S)

### Embodiment

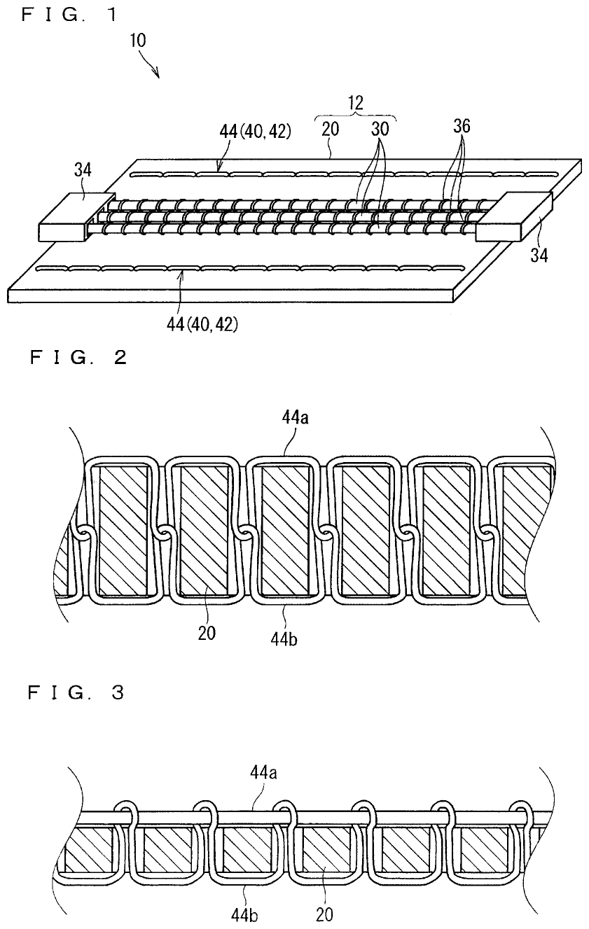

A wire harness according to an embodiment is described hereinafter. FIG. 1 is a perspective view illustrating a wire harness 10 according to the embodiment. FIG. 2 is a partial schematic cross-sectional view illustrating the wire harness 10 according to the embodiment.

The wire harness 10 includes an electrical wire with sheet material 12 and a tension bearing part 40.

The electrical wire with sheet material 12 includes a sheet material 20 and electrical wires 30 fixed to the sheet material 20.

Applicable is any sheet material 20 to which the electrical wire 30 can be fixed, herein, to which the electrical wire 30 can be sewn, thus a material and a thickness are not particularly limited. However, the wire harness 10 according to the present invention is preferable in a case where the sheet material 20 is more stretchable than the electrical wire 30 (herein, a case where the sheet material 20 stretches with a smaller force than the electrical wire 30 when the sheet material 20 is pulled), thus in the description hereinafter, the sheet material 20 is more stretchable than the electrical wire 30. Herein, a degree of elasticity corresponding to pulling and a section area, for example, are normally associated with stretch properties at the time of pulling the sheet material 20.

The sheet material 20 is considered a non-woven cloth, a woven cloth, or an extrusion molded sheet, for example. A material of the sheet material 20 is a synthetic resin of polyethylene (PE), polypropylene (PP), polyethylene terephthalate (PET), or polyvinyl chloride (PVC), or a natural material may also be used. There may also be a case where the sheet material 20 is formed of stacked layers each made up of different type of material.

Also considered as a usage of the sheet material 20 is a member for protecting the electrical wire 30, soundproofing, waterproof, or a member for attaching the electrical wire 30 to a mounting object (for example, a reinforcement material, a panel, or a trim) in a vehicle. There may also be a case where a metallic foil, for example, is stacked on the sheet material 20 to use the sheet material 20 for heat radiation. The usage of the sheet material 20 is not limited to one, but the sheet material 20 may be used for a plurality of purposes.

The electrical wire 30 includes a core wire and a covering for covering the core wire. The core wire is a linear conductor formed of a metal, and herein, the core wire is formed by twisting a plurality of elemental wires. The covering is formed of an insulating material such as a resin. The covering is formed by extrusion-covering a softened resin around the core wire, for example. However, there may also be a case where the electrical wire 30 is a so-called bare wire which does not include the covering. An end portion of the electrical wire 30 is connected to a connector 34 via a terminal, for example.

Herein, the electrical wire 30 is fixed to the sheet material 20 by sewing. Herein, the electrical wire is sewn to the sheet material 20 with a machine-sewing thread 36. Particularly herein, the electrical wire 30 is provided separately from a needle thread and a bobbin thread of the machine-sewing thread 36, and is sewn to the sheet material 20 with the needle thread and the bobbin thread. However, there may also be a case where the electrical wire 30 constitutes the needle thread or the bobbin thread of the machine-sewing thread 36 and is sewn to the sheet material 20.

In the example illustrated in FIG. 1, the electrical wire 30 is linearly disposed on the sheet material 20. However, there may also be a case where the electrical wire 30 is curvedly disposed on the sheet material 20. There may also be a case where the electrical wires 30 are halfway branched on the sheet.

In the description herein, at least one of the connectors 34 provided on the both end portions of the electrical wire 30 is fixed to the sheet material 20, however, the connector 34 may not be fixed to the sheet material 20.

The tension bearing part 40 is provided on the sheet material 20. The tension bearing part 40 bears part of tension applied to the electrical wire 30 in a state where the tension is applied to the electrical wire with sheet material 12. The tension bearing part 40 may be provided along an extension direction of the electrical wire 30 in a region where the electrical wire 30 is fixed. For example, in the example illustrated in FIG. 1, the electrical wire 30 extends in one direction, thus the tension bearing part 40 also extends in one direction. When the electrical wire 30 is halfway curved and extends in two or more directions, the tension bearing part 40 may also extend in two or more directions.

A material and shape of the tension bearing part 40, for example, are set to correspond to the tension applied to the electrical wire with sheet material 12 and characteristics of the electrical wire 30. More specifically, when the tension bearing part 40 is not provided, the tension applied to the electrical wire with sheet material 12 is divided between the sheet material 20 and the electrical wire 30. At this time, when the tension applied to the electrical wire 30 exceeds an allowable value of the electrical wire 30, there is a possibility that the electrical wire 30 is fractured. In contrast, the tension bearing part 40 is provided herein, thus the tension bearing part 40 bears part of the tension applied to the electrical wire with sheet material 12, thereby being able to reduce the tension applied to the electrical wire 30 to be smaller than the allowable value. Herein, when the sheet material 20 stretches easily, the tension applied to the electrical wire 30 increases. Even in such a case, the tension bearing part 40 is provided, thus the tension applied to the electrical wire 30 can be easily made smaller than the allowable value.

The tension bearing part 40 is preferably formed to be less stretchable than a part in the sheet material 20 where the electrical wire 30 is fixed. Accordingly, the tension bearing part 40 can bear the tension larger than that applied to the sheet material 20, thus the tension applied to the electrical wire 30 can be easily made smaller than the allowable value. Any tension bearing part 40 is applicable as long as it can reduce the tension applied to the electrical wire 30 to be smaller than the allowable value, thus there may also be a case where the tension bearing part 40 is formed to be more stretchable than the sheet material 20.

The tension bearing part 40 is preferably formed to be less stretchable than the electrical wire 30. Accordingly, the tension bearing part 40 can bear the tension larger than that applied to the electrical wire 30, thus the tension applied to the electrical wire 30 can be easily made smaller than the allowable value. Any tension bearing part 40 is applicable as long as it can reduce the tension applied to the electrical wire 30 to be smaller than the allowable value, thus there may also be a case where the tension bearing part 40 is formed to be more stretchable than the electrical wire 30.

Considered herein are a case where the tension bearing part 40 is formed of a material as stretchable as or more stretchable than the sheet material 20 and the electrical wire 30 (a material having a low degree of elasticity) and a case where the tension bearing part 40 is formed of a material less stretchable than the sheet material 20 and the electrical wire 30 (a material having a high degree of elasticity). In the former case, a section area of the tension bearing part 40 is made larger than a section area of the sheet material 20 or the electrical wire 30, thus the tension bearing part 40 can be formed less stretchable than the sheet material 20 or the electrical wire 30. In the latter case, the section area of the tension bearing part 40 can be made smaller than the section area of the sheet material 20 or the electrical wire 30 while the tension bearing part 40 is formed to be less stretchable than the sheet material 20 or the electrical wire 30. Even in the latter case, it is obvious that there may be a case where the section area of the tension bearing part 40 is made equal to or larger than the section area of the sheet material 20 or the electrical wire 30.

Specifically, the tension bearing part 40 herein includes a reinforcement member 42 provided as a member different from the electrical wire with sheet material 12.

When the reinforcement member 42 is provided as the tension bearing part 40 separately from the sheet material 20, the reinforcement member 42 is preferably formed of a material less stretchable than the material of the sheet material 20. Accordingly, a section area of the reinforcement member 42 can be reduced. For example, when the material of the sheet material 20 is the synthetic resin described above, considered as the material less stretchable than the sheet material 20 is metal or fiber having high degree of elasticity such as carbon fiber, polypara-phenylene benzobisoxazole (PBO) fiber, aramid fiber, high-strength polyethylene fiber, polyarylate fiber, glass fiber, for example.

Particularly, the reinforcement member 42 preferably includes a hardly-stretchable member formed of a material less stretchable than that of the electrical wire 30. For example, when the core wire of the electrical wire 30 is formed of a material of copper or copper alloy, considered as the material of the reinforcement member 42 are steel, carbon fiber, PBO fiber, aramid fiber, high-strength polyethylene fiber, for example. For example, when the core wire of the electrical wire 30 is made of aluminum or aluminum alloy, considered as the material of the reinforcement member 42 are those described in the above example in the case where the core wire is made of the material of copper or copper alloy, and copper or copper alloy may also be used the material of the reinforcement member 42.

The tension bearing part 40 preferably has tension strength large enough not be fractured by the tension applied to the tension bearing part 40. Accordingly, the tension bearing part 40 can be resistant to a repetitive pulling.

Herein, a thread 44 is sewn to the sheet material 20 as the reinforcement member 42. The thread 44 is linearly sewn along the extension direction of the electrical wire 30 on the sheet material 20. In the example illustrated in FIG. 1, the threads 44 are sewn in a manner of each extending in the extension direction of the sheet material 20 in both ends of the sheet material 20 along a width direction thereof. The threads 44 in the both ends may be formed of the same material or a material different from each other. At least one of the threads 44 in the both ends is preferably a hardly-stretchable member.

At this time, the thread 44 as the reinforcement member 42 is used as a machine-sewing thread and directly sewn to the sheet material 20. In an example illustrated in FIG. 2, the thread 44 as the reinforcement member 42 constitutes a needle thread 44a and a bobbin thread 44b of the machine-sewing thread. The needle thread 44a and the bobbin thread 44b may be made of the same material or a material different from each other.

There may also be a case where one of the needle thread 44a and the bobbin thread 44b extends along a surface of the sheet material 20 by changing thread tension in a machine sewing. In an example illustrated in FIG. 3, the needle thread 44a extends along the surface of the sheet material 20, however, it is also applicable that the bobbin thread 44b extends along the surface of the sheet material 20. When the needle thread 44a and the bobbin thread 44b are made of the different materials and one of the threads 44a and 44b is sewn along the surface of the sheet material 20, the thread 44 sewn along the surface of the sheet material 20 (the needle thread 44a in the example illustrated in FIG. 3) is preferably a thread having a high degree of elasticity. The reason is that the thread 44 sewn along the surface of the sheet material 20 has a shorter extra length than the other thread 44, and is likely to bear the tension. The thread 44 sewn along the surface of the sheet material 20 may be sewn along the surface of the sheet material 20 on a side where the electrical wire 30 is disposed, or may also be sewn along the surface of the sheet material 20 on a side opposite to the side where the electrical wire 30 is disposed.

There may also be a case where a thread having a higher degree of elasticity than that of a needle thread and a bobbin thread of a machine-sewing thread is provided separately from the needle thread and the bobbin thread of the machine-sewing thread, and is sewn to the sheet material 20 with the needle thread and the bobbin thread. In this case, the thread 44 provided separately from the needle thread and the bobbin thread of the machine-sewing thread 36 is sewn with the needle thread and the bobbin thread of the machine-sewing thread 36 in the manner similar to the electrical wire 30.

According to the above configuration, the tension bearing part 40 is provided, thereby being able to reduce the tension applied to the electrical wire 30. More specifically, when the tension is applied to the electrical wire with sheet material 12, the tension can be divided between the sheet material 20, the electrical wire 30, and the tension bearing part 40. Accordingly, the tension applied to the electrical wire 30 can be made small compared with the case where the tension bearing part 40 is not provided.

Since the tension bearing part 40 includes the reinforcement member 42 provided as the member different from the electrical wire with sheet material 12, the tension bearing part 40 corresponding to the tension applied to the electrical wire with sheet material 12 can be simply provided. The reinforcement member 42 can also be made of a material having a higher degree of elasticity than a material constituting the sheet material 20 and the electrical wire 30.

The reinforcement member 42 includes the thread 44 sewn to the sheet material 20, thus when the electrical wire 30 is sewn and fixed to the sheet material 20, for example, the thread 44 as the reinforcement member 42 can be sewn to the sheet material 20 using the same facility.

The thread 44 is linearly sewn to the sheet material 20, thus the thread 44 has a short extra length and is likely to bear the tension applied to the electrical wire with sheet material 12.

The reinforcement member 42 includes the hardly-stretchable member formed of the material less stretchable than the electrical wire 30, thus can bear a larger ratio of the tension applied to the electrical wire with sheet material 12.

The electrical wire 30 is sewn and fixed to the sheet material 20, thus the electrical wire 30 can be simply fixed to the sheet material 20.

The connector 34 is fixed to the sheet material 20 or the sheet material 20 is fixed to the other member, for example, thus the sheet material 20 can receive the tension applied to the end portion of the electrical wire 30 when the electrical wire with sheet material 12 is pulled. Accordingly, a terminal on the end portion of the electrical wire 30 hardly gets out of the connector 34. In the similar manner, the end portion of the electrical wire 30 hardly gets out of the terminal. Accordingly, terminal holding force in the connector 34 and terminal holding force in the end portion of the electrical wire 30 can be easily ensured without significantly changing a shape of a housing of the connector 34 and a shape of the terminal, for example.

### Modification Example

Also considered is a case where the reinforcement member 42 includes a dummy electrical wire 30 provided together with the electrical wire 30 and fixed to the sheet material 20. For example, considered in the example illustrated in FIG. 1 is that one or two of the three electrical wires 30 are the electrical wires 30 constituting a circuit and the remaining one or two are used as the dummy electrical wires 30. In this case, the dummy electrical wire 30 is preferably formed to be less stretchable than the electrical wire 30. For example, it is considered that the dummy electrical wire 30 is thicker than the electrical wire 30 in a case where the dummy electrical wire 30 and the electrical wire 30 are made of the same material. Also considered, for example, is that the dummy electrical wire 30 is formed of a less-stretchable material.

According to such a configuration, when the electrical wire 30 is fixed to the sheet material 20, the dummy electrical wire 30 can be fixed to the sheet material 20 by the same fixing method. For example, the tension applied to the end portion of one electrical wire 30 can be simply reduced by inserting the dummy electrical wire 30 in an empty cavity in the connector 34.

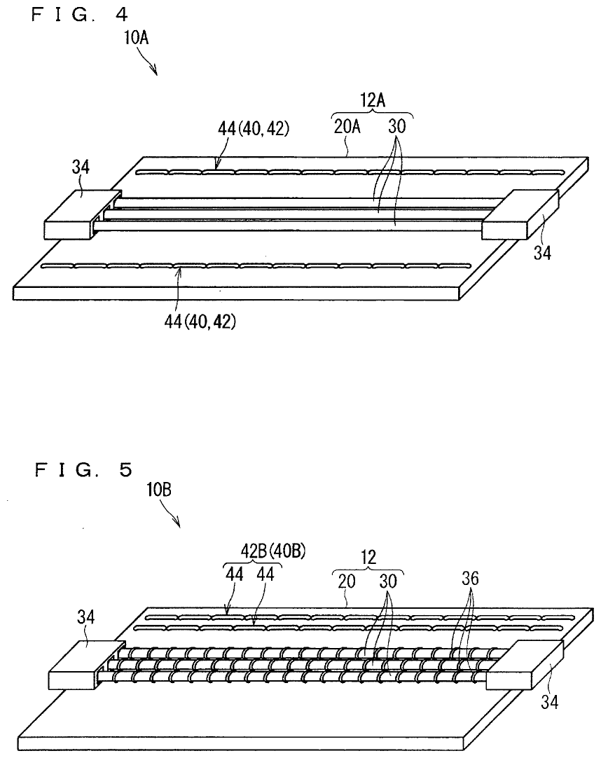

FIG. 4 is a perspective view illustrating a wire harness 10A according to a first modification example.

In the description of the embodiment, the electrical wire 30 is fixed to the sheet material 20 by sewing, however, the method of fixing the electrical wire 30 to the sheet material 20 is not limited thereto described above. The electrical wire 30 may be fixed to the sheet material 20 by an adhesive agent, for example.

In the wire harness 10A according to the present modification example, the electrical wire 30 is fixed to the sheet material 20A by welding to constitute an electrical wire with sheet material 12A. Also in this case, the electrical wire 30 and the sheet material 20A can be simply fixed to each other.

Applicable in the present modification example is the sheet material 20A enabling the welding of the electrical wire 30. In this case, it is preferable that an insulating covering covering the core wire in the electrical wire 30 and the sheet material 20A are welded to each other, and it is particularly preferable that the insulating covering and the sheet material 20A are formed of a material of the same type of synthetic resin. Ultrasonic welding is preferable as the welding method, however, laser welding, for example, is also applicable.

A position where the electrical wire 30 and the sheet material 20 are welded may be intermittently located along the extension direction of the electrical wire 30, or may be continuously located.

When the electrical wire 30 is fixed to the sheet material 20A by welding, considered is that the tension bearing part 40 is also formed by welding.

FIG. 5 is a perspective view illustrating a wire harness 10B according to a second modification example.

In the wire harness 10B according to the present modification example, a position of a tension bearing part 40B and the number of reinforcement members 42B are different from those in the other example described above.

In the above description, the tension bearing parts 40 are provided on the both ends of the sheet material 20, however, this configuration is not necessary. As illustrated in FIG. 5, there may also be a case where the tension bearing part 40B is provided on only one end side of the sheet material 20 and is not provided on the other end side thereof. Although the illustration is omitted, there may also be a case where a tension bearing part is provided between the electrical wires 30.

In the above description, the thread 44 as the reinforcement member 42 in a form of one line is sewn to one end portion, however, this configuration is not necessary. There may also be a case where the thread 44 as the reinforcement member 42B in a form of two or more lines (two lines in the example illustrated in FIG. 5) is sewn on the one end side.

FIG. 6 is a perspective view illustrating a wire harness 10C according to a third modification example.

In the above description, the thread 44 sewn to the sheet material 20 is used as the reinforcement member 42, however, a shape of the reinforcement member 42 is not limited to that of the thread 44.

In the wire harness 10C according to the present modification example, a shape of the reinforcement member 42C is different from those in the other example described above. Herein, a plate material 46 is fixed to the sheet material 20 as the reinforcement member 42C. A material similar to that of the thread 44 described above can be used as a material of the plate material 46, or a material more stretchable than that of the thread 44 described above can also be used. Particularly when the plate material 46 is applied, a section area thereof can be made larger than the case of applying the thread 44, thus even when a material more stretchable than that of the thread 44 described above is used, the plate material 46 can bear large tension.

The plate material 46 is attached to the sheet material 20. The plate material 46 is attached to the sheet material 20 by an attaching member such as an adhesive agent or a double-sided adhesive tape, for example. Also considered is that the plate material 46 is attached to the sheet material 20 by welding, for example, without using the attaching member.

As described above, the reinforcement member 42 is not limited to the thread 44, however various shapes can be adopted. Particularly when the plate material 46 is applied, the section area can be simply made larger than the case of applying the thread 44. An area of contact of the plate material 46 with the sheet material 20 can be made large, thus the plate material 46 can be simply attached to the sheet material 20.

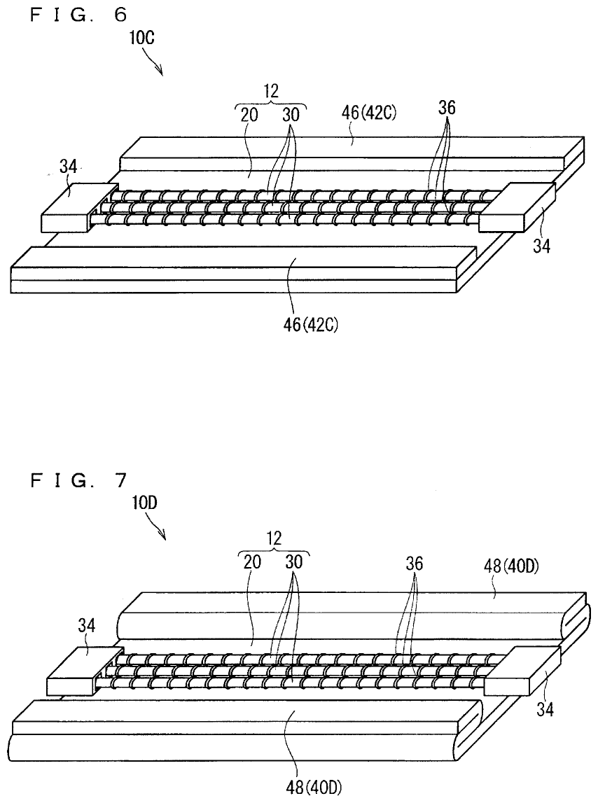

FIG. 7 is a perspective view illustrating a wire harness 10D according to a fourth modification example.

In the above description, the tension bearing part 40 includes the reinforcement member 42 provided as the member different from the electrical wire with sheet material 12, however, this configuration is not necessary. There may also be a case where the tension bearing part 40 is formed by a part of the sheet material 20. Herein, the tension bearing part 40D includes a folding part 48 formed by folding back the part of the sheet material 20.

In an example in FIG. 7, the folding part 48 is threefold by folding back the end portion of the sheet material 20 twice. However, the folding part 48 may be twofold, or may also be fourfold or more.

The folding part 48 is fixed in a folded-back state. Considered is that the attaching member such as the adhesive agent or the double-sided adhesive tape is used when the folding part 48 is fixed in the folded-back state. A thread for sewing the part which is folded back is also considered as the attaching member. Also considered is that the folding part 48 is fixed by welding, for example, without using the attaching member.

The folding part 48 is also considered to be compressed, for example. In this case, the folding part 48 has a higher degree of elasticity than the other part of the sheet material 20. The section area is reduced when the folding part 48 is compressed.

According to the above configuration, the folding part 48 is provided in the sheet material 20, thus the tension bearing part 40D can be simply provided using the sheet material 20.

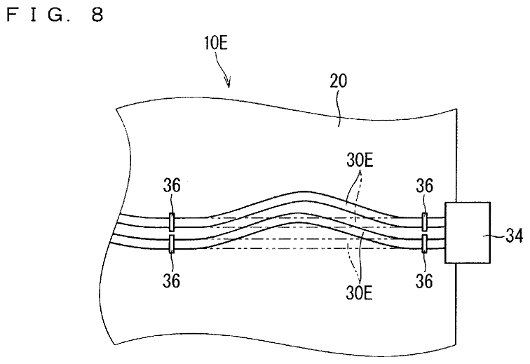

FIG. 8 is a perspective view illustrating a wire harness 10E according to a fifth modification example.

In the above description, the electrical wire 30 is provided to extend along a shortest path in a predetermined arrangement path on the sheet material 20, however, this configuration is not necessary. Also considered is a configuration that part of the electrical wire 30 disposed on the sheet material 20 bends or winds, so that the electrical wire 30 does not extend along the shortest path and an extra length part is formed. There may also be a case where the predetermined arrangement path is not straight but curved.

For example, when the electrical wire 30 is discontinuously fixed to the sheet material 20 along the longitudinal direction, the electrical wire 30 may bend or wind in a part between parts fixed to the sheet material 20, thereby generating the extra length part. In the example illustrated in FIG. 8, a part of the electrical wire 30E between parts sewn to the sheet material 20 by the machine-sewing thread 36 bends, and the extra length part is generated compared with the case where the electrical wire 30E extends along the shortest path (the case indicated by a virtual line in FIG. 8). Accordingly, even when the tensile force is applied to the wire harness 10E along the extension direction of the electrical wire 30E, the tensile force tends to be applied to the sheet material 20 first. As a result, it is possible to suppress the excess tensile force applied to the electrical wire 30. A case where the tensile force is applied to the electrical wire 30E via the connector 34, such as a case of hooking the connector 34, often falls under the case where the excess tensile force is actually applied, thus it is effective to provide such an extra length part provided near the connector 34.

Each configuration described in the embodiment and each modification example can be appropriately combined as long as they are not contradictory. For example, also considered is that a plurality of configurations are combined as the tension bearing part 40 such as adopting both the thread 44 and the folding part 48 as the tension bearing part 40. In this case, the plurality of configurations may be adopted in one position on the sheet material 20, or the plurality of configurations may be adopted in different positions on the sheet material 20.

Although the present invention is described in detail, the foregoing description is in all aspects illustrative and does not restrict the invention. It is therefore understood that numerous modifications and variations can be devised without departing from the scope of the invention.

### EXPLANATION OF REFERENCE SIGNS

10 wire harness
12 electrical wire with sheet material
20 sheet material
30 electrical wire
34 connector
36 machine-sewing thread
40 tension bearing part
42 reinforcement member
44 thread
46 plate material
48 folding part

1. A wire harness, comprising:
an electrical wire with sheet material including a sheet material and an electrical wire fixed onto the sheet material; and
a tension bearing part provided on the sheet material to bear part of tension applied to the electrical wire in a state where the tension is applied to the electrical wire with sheet material.

2. The wire harness according to claim 1, wherein
the tension bearing part includes a reinforcement member provided as a member different from the electrical wire with sheet material.

3. The wire harness according to claim 2, wherein
the reinforcement member includes a thread sewn to the sheet material.

4. The wire harness according to claim 3, wherein
the thread is linearly sewn to the sheet material.

5. The wire harness according to claim 2, wherein
the reinforcement member includes a dummy electrical wire provided together with the electrical wire, and fixed to the sheet material, and not constituting a circuit.

6. The wire harness according to claim 2, wherein
the reinforcement member includes a hardly-stretchable member formed of a material less stretchable than a material of the electrical wire.

7. The wire harness according to claim 1, wherein
the tension bearing part includes a folding part formed by folding back part of the sheet material.

8. The wire harness according to claim 1, wherein
the electrical wire is fixed to the sheet material by sewing or welding.

9. The wire harness according to claim 2, wherein
the reinforcement member is provided on the sheet material.

10. The wire harness according to claim 1, wherein
the tension bearing part is formed to be less stretchable than a part in the sheet material where the electrical wire is fixed.

11. The wire harness according to claim 1, wherein
the sheet material includes an extrusion molded sheet.
